(19) United States
(12) Patent Application Publication
(10) Pub. No.: US 2026/0180502 A1
(43) Pub. Date: Jun. 25, 2026

(54) SOLAR PANEL ASSEMBLY

(71) Applicant: Abhinav S. Verma, Dubai (AE)

(72) Inventor: Abhinav S. Verma, Dubai (AE)

(21) Appl. No.: 19/540,595

(22) Filed: Feb. 14, 2026

Related U.S. Application Data
(63) Continuation-in-part of application No. 18/744,632, filed on Jun. 16, 2024, now Pat. No. 12,556,133.

(51) Int. Cl. H02S 30/20; H02S 10/40; H02S 30/10; H10F 19/80

(52) U.S. Cl. CPC H02S 30/20; H02S 10/40; H02S 30/10; H10F 19/80

(57) ABSTRACT

A solar panel assembly for a vehicle includes a housing and at least one movable solar panel configured for extension and retraction. An intelligent central controller executes sensor fusion logic to manage panel deployment based on real-time environmental data received from distributed light, motion, and proximity sensors. The assembly includes shade-avoidance logic for partial panel deployment to optimize energy harvest, a vehicle motion fail-safe for automatic emergency retraction, and a safety interlock to inhibit vehicle operation during mechanical malfunctions. An integrated power distribution module features external outlets and a waterproof storage compartment managed by smart power-sharing logic to allocate energy between a vehicle battery and external loads. The assembly is hardwired into the vehicle's electrical architecture and facilitates hands-free operation via user-presence detection or a mobile application interface.

### CROSS-REFERENCE TO RELATED APPLICATIONS

This application is a continuation-in-part of U.S. patent application Ser. No. 18/744,632 filed on Jun. 16, 2024. The entire disclosure of the foregoing application is hereby expressly incorporated by reference herein.

### FIELD OF THE INVENTION

This application relates to a solar panel assembly that may be extended and retracted

### BACKGROUND OF THE INVENTION

Solar cells may be used to power electric vehicles from sunlight and are an excellent source of clean energy. Solar vehicles typically contain a rechargeable battery to help regulate and store the energy from the solar cells. The design of solar vehicles always emphasizes energy efficiency to make maximum use of the limited amount of energy they can receive from sunlight. Solar cells may be mounted on the exterior of vehicles so that they are exposed to the sunlight to power them. The larger the surface area of the solar cell exposed to the sunlight, the more power can be supplied to the electric vehicle. However, there is limited room on the exterior of the vehicles for the solar cell. Further, there are locations on the exterior body of the vehicle such as the windows in which placement of the solar cell would obstruct the view through window.

Hence it is an object of the present invention to maximize the supply of solar power to charge a vehicle.

Despite these advancements, conventional vehicle-mounted solar systems often suffer from significant efficiency losses due to partial shading from nearby structures or environmental obstacles. Furthermore, existing systems lack integrated intelligence to manage automated deployment based on user proximity, environmental safety conditions, or smart power distribution to external loads. There remains a need for an integrated solar panel assembly that combines high-efficiency generation with a sensor-fusion control architecture to optimize performance, safety, and utility in diverse operational environments.

### SUMMARY OF THE INVENTION

In one aspect of the present invention, a solar panel assembly for a vehicle is provided. The assembly comprises a housing including a top solar panel, a bottom cover panel, and a frame, with at least one movable solar panel configured to move between a retracted position within the housing and an extended position outside the housing. A central controller is disposed within the housing and comprises a processor and a sensor fusion module. The assembly includes a light sensor in communication with the central controller, wherein the central controller is configured to detect a transition from a sunlit region to a shadowed region via the light sensor and automatically halt extension of the movable solar panel at an intermediate position based on said transition.

In another aspect of the present invention, a solar panel assembly for a vehicle is provided comprising a housing with at least one movable solar panel and a central controller having a power management unit. The assembly further comprises an integrated power distribution module including at least one external power outlet and an integrated waterproof storage compartment. A motion sensor is configured to detect vehicle movement, and the central controller is configured to initiate an emergency retraction of the movable solar panel upon detection of vehicle movement via the motion sensor.

In another aspect of the present invention, a solar panel assembly for a vehicle is provided comprising a housing containing at least one movable solar panel and a central controller comprising a sensor fusion module and a communication transceiver. A proximity sensor is provided in communication with the central controller. The central controller is configured to identify a presence of an authorized user within a predefined radius of the vehicle via the proximity sensor and automatically move the movable solar panel between a retracted and extended position based on the presence of the authorized user.

Other aspects of the disclosed invention will become apparent from the following detailed description, the accompanying drawings and the appended claims.

### BRIEF DESCRIPTION OF THE DRAWINGS

The accompanying drawings are included to provide a further understanding of the invention and are incorporated into and constitute a part of the specification. They illustrate one embodiment of the invention and, together with the description, serve to explain the principles of the invention.

FIG. 1 is a top, front, and right side perspective view of the solar panel assembly in a retracted position according to a first embodiment of the present invention.

FIG. 2 a top, rear, and left side perspective view of the solar panel assembly of FIG. 1.

FIG. 3 a bottom view of the solar panel assembly of FIG. 1 in an extended position.

FIG. 4 is a top, front, and left side perspective view of a portion of the solar panel assembly of FIG. 1 with the front frame member and other portions removed for illustrative purposes.

FIG. 5 is a top and left perspective view of a portion of the solar panel assembly of FIG. 1 with portions removed to show the right frame member, right upper and lower rails, and the right upper and lower racks.

FIG. 6 is a top, front, and right perspective view of the solar panel assembly of FIG. 1 mounted on a vehicle in the extended position.

FIG. 7 is a top, rear, and right side view of a portion of the front solar panel and related parts of the solar panel assembly of FIG. 1 illustrating the mechanism that extends and retracts the front solar panel.

FIG. 8 is a top, rear, and left side view of a portion of the front solar panel and related parts of the solar panel assembly of FIG. 1 illustrating the mechanism that extends and retracts the front solar panel.

FIG. 9 is a top, front, and right side view of a portion of the rear solar panel and related parts of the solar panel assembly of FIG. 1 illustrating the mechanism that extends and retracts the rear solar panel.

FIG. 10 is a top, front, and left side view of a portion of the rear solar panel and related parts of the solar panel assembly of FIG. 1 illustrating the mechanism that extends and retracts the rear solar panel.

FIG. 11 is a right side view of the solar panel assembly of FIG. 1 mounted on a vehicle roof rack.

FIG. 12 is a left side view of the solar panel assembly of FIG. 1 mounted on a vehicle roof rack.

FIG. 13 is a is a top, front, and right perspective view of the solar panel assembly of FIG. 1 mounted on a vehicle in a retracted position.

FIG. 14 is a rear and left side perspective view of a portion of the solar panel assembly of FIG. 1 in the retracted position with the left side frame member removed for illustrative purposes.

FIG. 15 is a rear and right side perspective view of a portion of the solar panel assembly of FIG. 1 in the retracted position with the right side frame member removed for illustrative purposes.

FIG. 16 is a rear and right side perspective view of a portion of the solar panel assembly of FIG. 1 in the retracted position with the right side frame member removed for illustrative purposes.

FIG. 17 is a rear and left side perspective view of a portion of the solar panel assembly of FIG. 1 in the retracted position with the left side frame member removed for illustrative purposes.

FIG. 18 is a left side perspective view of a portion of the solar panel assembly of FIG. 1 in the retracted position with the left side frame member removed for illustrative purposes.

FIG. 19 is a right side perspective view of a portion of the solar panel assembly of FIG. 1 in the retracted position with the right side frame member removed for illustrative purposes.

FIG. 20 is a top and right side perspective view of a rear portion of the front solar panel of the solar panel assembly of FIG. 1.

FIG. 21 is a top and left side perspective view of a front portion of the rear solar panel of the solar panel assembly of FIG. 1.

FIG. 22 is a top perspective view of a front portion of the front solar panel of the solar panel assembly of FIG. 1

FIG. 23 is a top perspective view of a rear portion of the rear solar panel of the solar panel assembly of FIG. 1

FIG. 24 is a top and left side perspective view of the solar panel assembly in the extended portions according to a second embodiment of the present invention.

FIG. 25 is a rear view of a right portion of the front solar panel and other portions of the solar panel assembly of FIG. 1 with portions removed to show a roller bearing in contact with the right lower rail and to show other elements of the solar panel assembly.

FIG. 26 is a rear view of a left portion of the front solar panel and other portions of the solar panel assembly of FIG. 1 with portions removed to show a roller bearing in contact with the left lower rail and to show other elements of the solar panel assembly.

FIG. 27 is a front view of a left portion of the rear solar panel and other portions of the solar panel assembly of FIG. 1 with portions removed to show a roller bearing in contact with the left upper rail and to show other elements of the solar panel assembly.

FIG. 28 is a front view of a right portion of the rear solar panel and other portions of the solar panel assembly of FIG. 1 with portions removed to show a roller bearing in contact with the right upper rail and to show other elements of the solar panel assembly.

FIG. 29 is a schematic view of a solar cells coupled to cell level bypass diodes of the solar panel assembly of FIG. 1.

FIG. 30 is a top view of another embodiment of the solar panel assembly of the present invention.

FIG. 31 is a schematic block diagram of the control architecture and sensor fusion logic of the solar panel assembly, illustrating the central controller (CC) in communication with a plurality of input sensors and output components.

FIG. 32 is a bottom view of the solar panel assembly of FIG. 1 in an extended position, modified from FIG. 3 of the parent application to illustrate the physical placement of the integrated power export outlets and the waterproof storage compartment.

FIG. 33 is a top, front, and right perspective view of the solar panel assembly of FIG. 1 mounted on a vehicle, modified from FIG. 6 of the parent application to illustrate an operational state wherein the front solar panel is halted at an intermediate deployment position upon the detection of a shaded region S by a light sensor.

### DETAILED DESCRIPTION OF THE INVENTION

It will be readily understood that the components of the embodiments as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments, as claimed, but is merely representative of example embodiments.

Furthermore, the described features, structures, or characteristics may be combined in any suitable manner in one or more embodiments. In the following description, numerous specific details are provided to give a thorough understanding of embodiments. One skilled in the relevant art will recognize, however, that the various embodiments can be practiced without one or more of the specific details, or with other methods, components, materials, etc. In other instances, well-known structures, materials, or operations are not shown or described in detail to avoid obfuscation. The following description is intended only by way of example, and simply illustrates certain example embodiments.

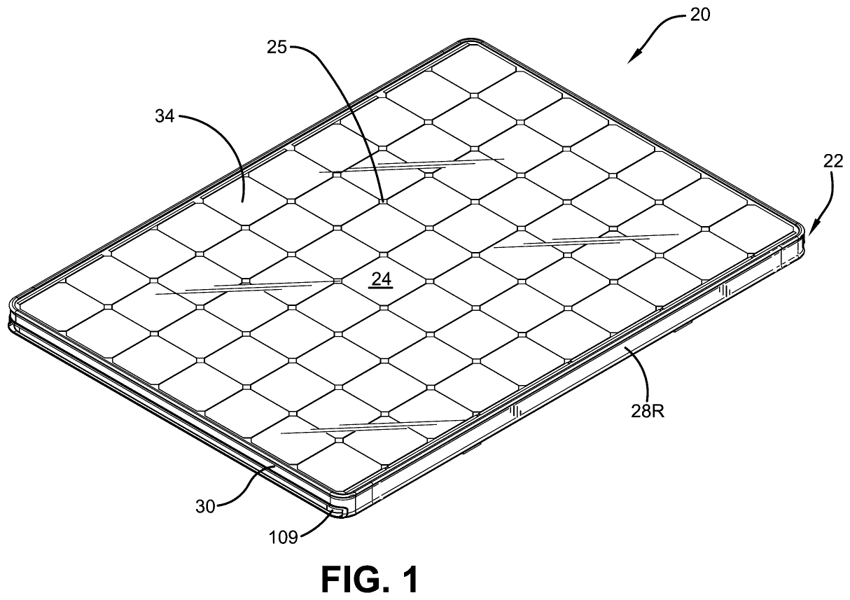

Throughout the present description, the terms “upper”, “lower”, “top”, “bottom”, “left”, “right”, “front”, “forward”, “rear”, and “rearward” shall define directions or orientations with respect to the apparatus as illustrated in FIG. 1, a top, front, and right side perspective view of the solar panel assembly in a retracted position. It will be understood that the spatially relative terms “upper”, “lower”, “top”, “bottom”, “left”, “right”, “front”, “forward”, “rear”, and “rearward” are intended to encompass different orientations of the apparatus in use or operation in addition to the orientation depicted in the figures. For example, if the apparatus in the figures is turned over, elements described as “upper” elements or features would then be “lower” elements or features.

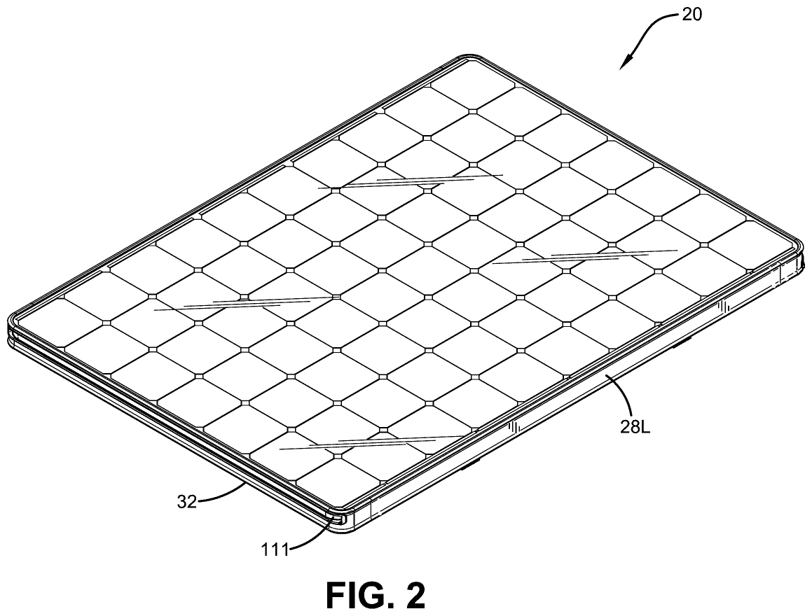

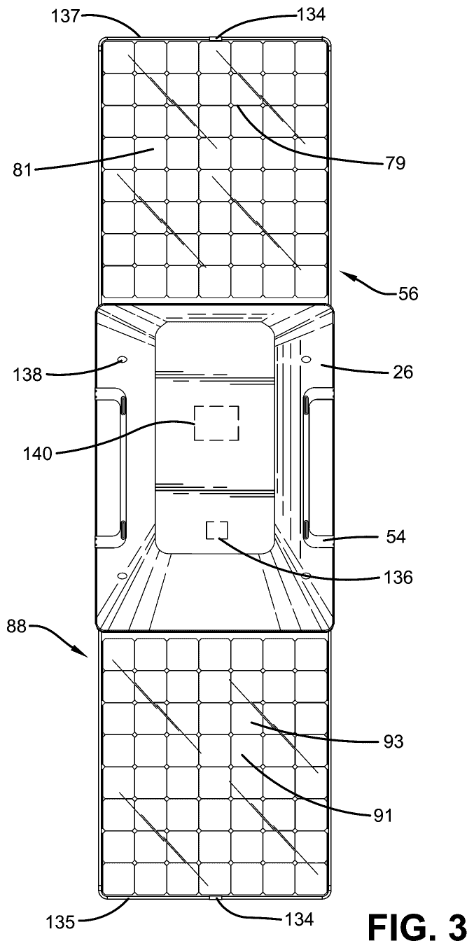

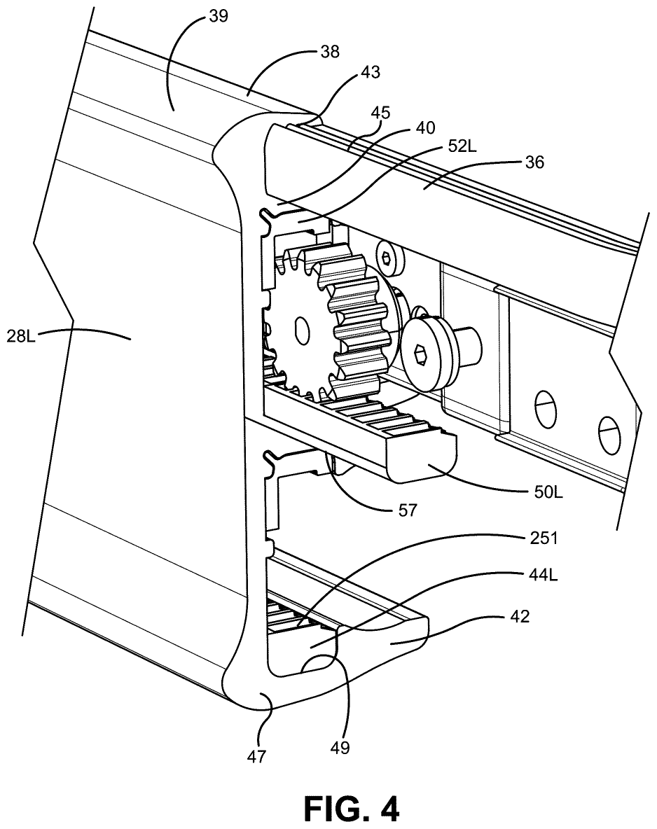

FIGS. 1 and 2 show a first embodiment of a solar panel assembly 20 in the retracted position. The solar panel assembly 20 comprises a main housing 22. The main housing 22 includes a top solar panel 24, bottom cover panel 26 (FIG. 3), right and left side frame members 28R, 28L, and front and rear side frame members 30, 32. The top solar panel 24 may be rectangular in shape and include a center body 25 that has solar cells 34 on top of the body 25. A top solar panel frame 36 (FIG. 4) surrounds the peripheral end of the body 25 and is attached to body 25.

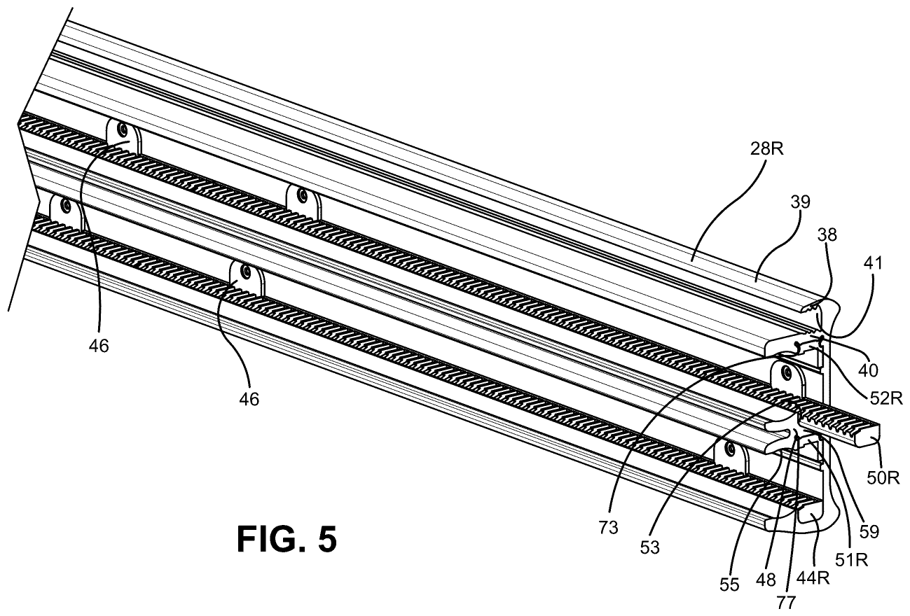

As illustrated in FIGS. 4 and 5, each of the right and left side frame members 28R, 28L includes upper and lower lips 38, 40 formed on a top end 39 of the side frame member that extend inwardly. The upper and lower lips 38, 40 define a channel 41 (FIG. 5) that securely receives the top solar panel frame 36. As depicted in FIG. 4, the upper lip 38 includes ribs 43 on its underside that depend downwardly and engage corresponding grooves 45 formed in the top surface of the top solar frame 36. Each of the right and left side frame members 28R, 29L includes a bottom end 47 in which a bottom lip 42 is attached thereto and extends inwardly from the bottom end 47. The bottom lip 42 includes a lower rack channel 49 that extends longitudinally (front to back) along the respective right or left side frame member. A right lower rack 44R (FIG. 5) is inserted into the lower rack channel 49 for the right side frame member 28R, and a left lower rack 44L is inserted into the lower rack channel 49 for the left side frame member 28L. The right and left lower racks 44R, 44L extend longitudinally along their respective lower rack channels 49. Each of the right and left lower racks 44R, 44L includes teeth 251 formed in its top surface. Each of the lower racks includes upper mounting tabs 46 (FIG. 5) that enable the lower rack to be mounted by fasteners to its respective left or right side frame member. Each of the right and left side frame members 28R, 28L also includes a medial holder 48 that is attached at approximately the midpoint between the top and bottom ends 39, 47. The medial holder 48 includes a body 59 and upper and lower holder lips 53, 55 (FIG. 5).

The medial holder 48 extends inwardly and includes an upper rack channel 57 (FIG. 4) in the top surface of its body 59 (FIG. 5) that extends longitudinally (front to back) along the side frame member. A right upper rack 50R is inserted into the upper rack channel 57 for the right side frame member 28R, and a left upper rack 50L is inserted into the upper rack channel 57 for the left side frame member 28L. The right and left upper racks 50R, 50L extend longitudinally along their respective upper rack channels 57. Each of the right and left upper racks 50R, 50L includes teeth 61 formed in its top surface. The upper and lower racks include upper mounting tabs 46 (FIG. 5) that enable the upper and lower racks to be mounted by bolts to the left or right side frame member.

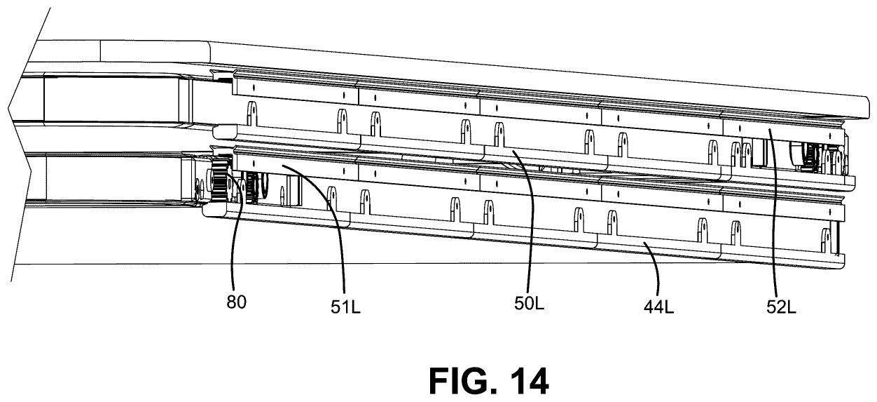

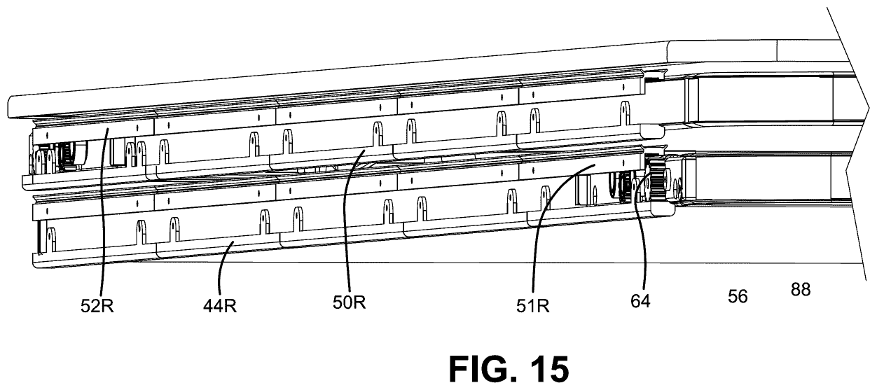

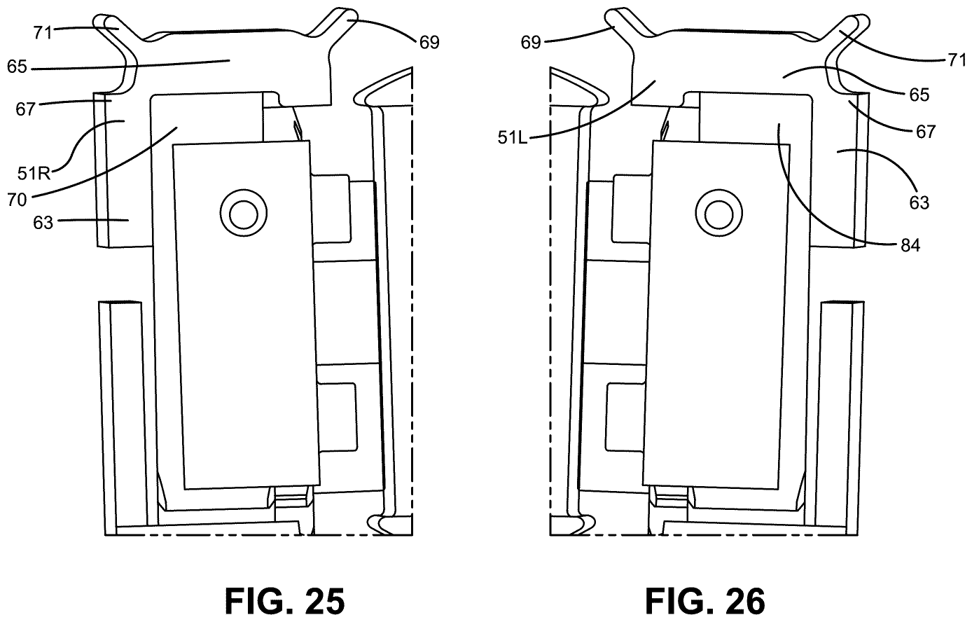

As illustrated in FIGS. 4, 5, 14, 15, 25, and 26, the solar panel assembly 20 further includes a pair of inverted L-shaped right and left lower rails 51R, 51L that are each attached to their respective right and left side frame member by bolts. As depicted in FIGS. 25 and 26, each lower rail includes a lower vertical leg 63 integrally formed in one piece with an upper horizontal leg 65 at an upper end 67 of the lower leg 63. The upper leg 65 extends inwardly from the upper end 67 of the lower leg 63. The upper leg 65 also includes a pair of inner and outer arms 69, 71 that extend diagonally and upwardly from the upper leg 65. The inner arm 69 extends upwardly and inwardly, and the outer arm 71 extends upwardly and outwardly relative to the solar panel assembly 20. The arms 69, 71 are inserted into corresponding arm channels 77 (FIG. 5) formed in the bottom side of the body 59 of the medial holder 48.

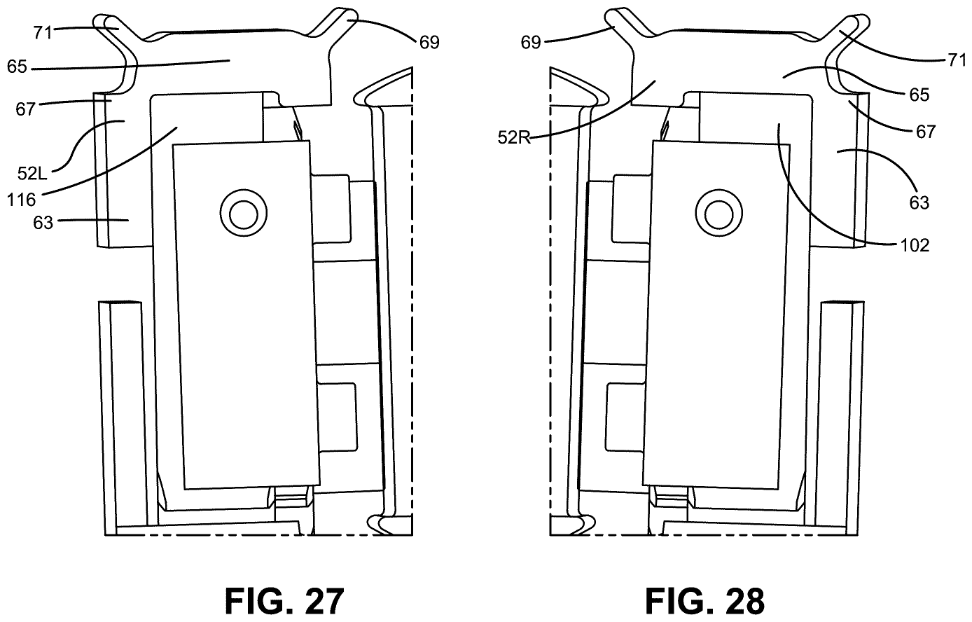

As illustrated in FIGS. 4, 5, 14, 15, 27, and 28, the solar panel assembly 20 further includes a pair of inverted L-shaped right and left upper rails 52R, 52L that are each attached to their respective right and left side frame member by bolts. As depicted in FIGS. 27 and 28, similar to each lower rail, each upper rail includes a lower vertical leg 63 integrally formed on one piece with an upper horizontal leg 65 at an upper end 67 of the lower leg 63. The upper leg 65 extends inwardly from the upper end of the lower leg. The upper leg 65 also includes a pair of inner and outer arms 69, 71 that extend diagonally and upwardly from the upper leg 65. The inner arm 69 extends upwardly and inwardly and the outer arm 71 extends upwardly and outwardly relative to the solar panel assembly 20. The arms 69, 71 are inserted into corresponding arm channels 73 (FIG. 5) formed in the bottom side of the lower lip 38 located at the top end of the side frame member. The bottom cover panel 26 is attached to the bottom of the right and left side frame members via brackets 54 (FIG. 3). The bottom cover panel 26 is waterproof to protect the solar panel assembly from water. Alternatively, or in addition, the bottom cover panel may include drain holes 138 (FIG. 3) and all electric components such as the inverter electrically insulated in a waterproof housing.

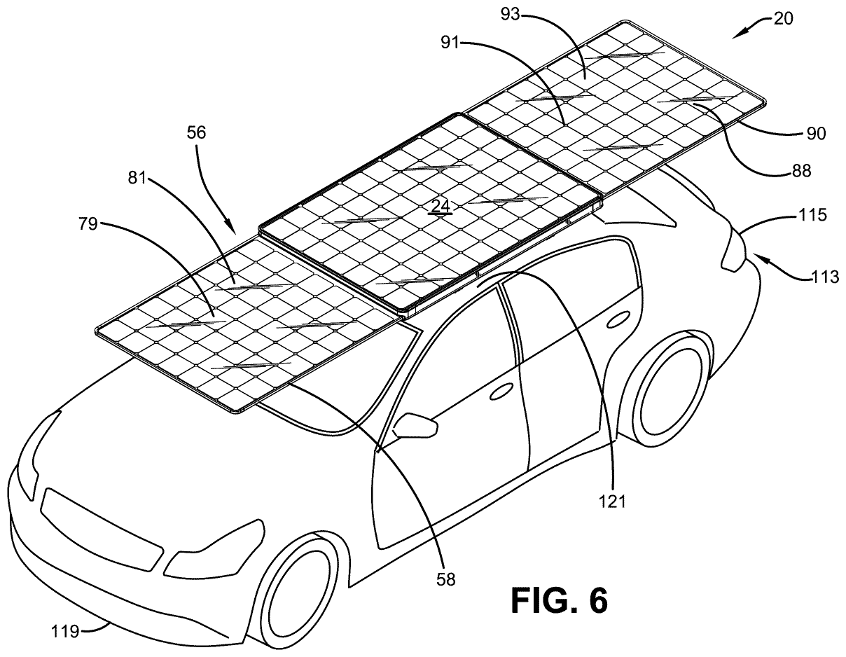

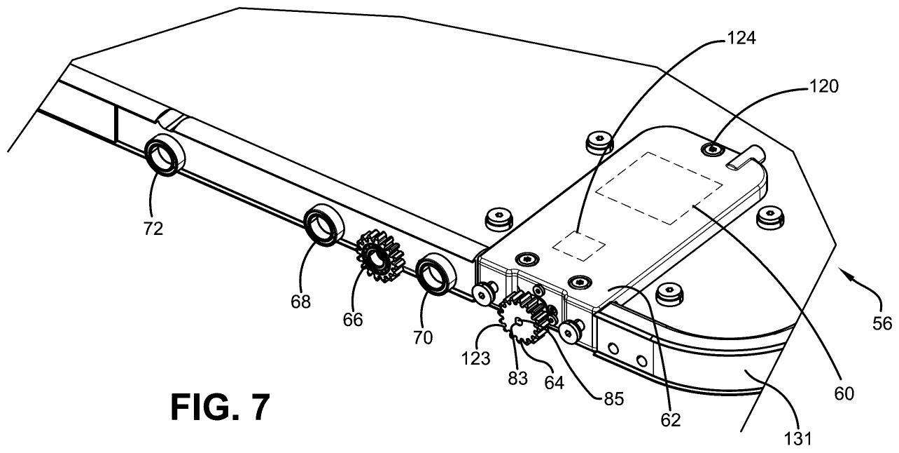

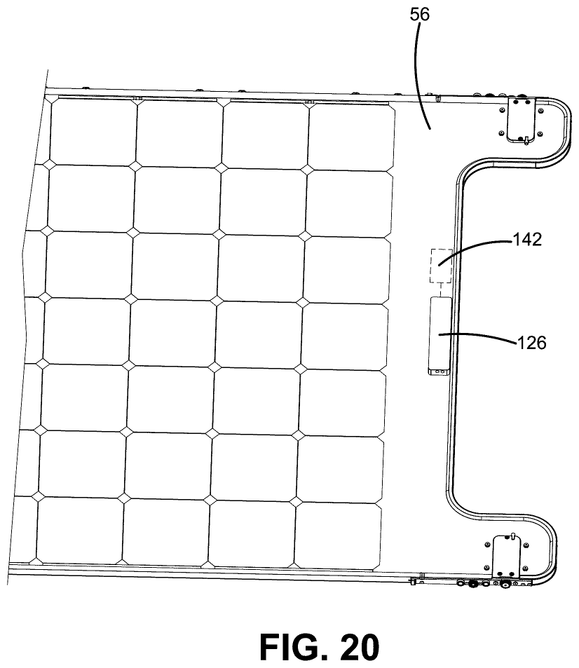

The solar panel assembly 20 also includes a front solar panel 56 as illustrated in FIGS. 3 and 6. The front solar panel 56 includes a body 79 that has solar cells 81 on both the top and bottom surface of the front solar panel 56. The front solar panel 56 includes a front solar panel frame 58 that surrounds the peripheral end of the body 79 and is attached to the body 79. As seen in FIG. 7, a first motor 60 is mounted in a first motor compartment 62 of the front solar panel frame 58 near the rear right corner of the front solar panel frame 58. The first motor 60 may be powered by a power source such as the vehicle battery or a small rechargeable battery 142 (FIG. 20) in the front solar panel 56. The battery 142 may be charged by the front solar panel 56. The first motor 60 includes a rotor or shaft 83 that is D-shaped in cross section. The rotor 83 of the first motor 60 extends through the first motor compartment 62, the right side of the front solar panel frame 58 and through a corresponding D-shaped bore 85 of a first pinion gear 64. The rotor 83 engages the first pinon gear, so that rotation of the rotor rotates the first pinion gear 64. A first roller bearing gear 66 is rotatably mounted to the right side of the front solar panel frame 58 and rotates freely. The first roller bearing gear 66 is located between first and second roller bearings 68, 70 located on the right side of the front solar panel frame. A third roller bearing 72 is located forwardly from the first roller bearing gear 66 and first roller bearing 68. The first, second, and third roller bearings are rotatably mounted on the exterior side of the front solar panel frame 58 with the rotating axes of the roller bearings being located higher than the axis of rotation of the first roller bearing gear 66, such that the highest points of the roller bearings 68, 70, 72 are higher than the highest point of the first roller bearing gear 66.

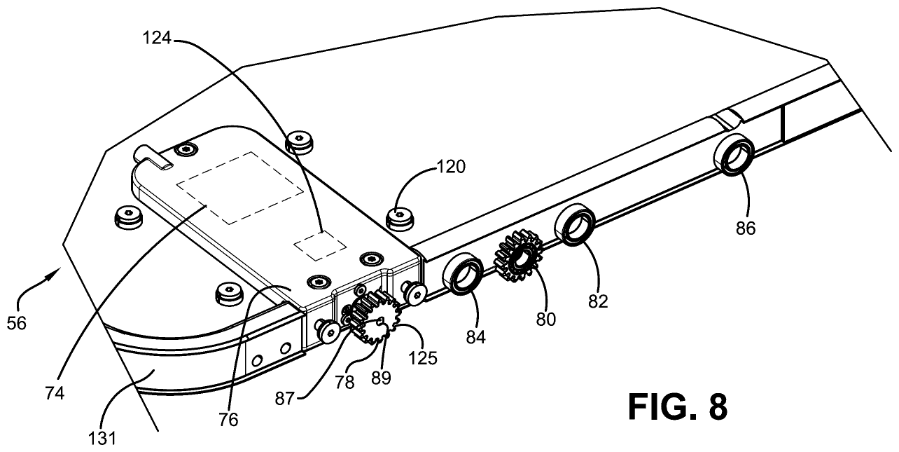

As illustrated in FIG. 8, a second motor 74 is mounted in a second motor compartment 76 of the front solar panel frame 58 near the rear left corner of the front solar panel frame 58. The second motor 74 may be powered by a power source such as the vehicle battery or the small rechargeable battery 142 (FIG. 20). The second motor 74 includes a rotor or shaft 87 that is D-shaped in cross section. The rotor 87 of the second motor 74 extends through the second motor compartment 76, the left side of the front solar panel frame 58 and through a corresponding D-shaped bore 89 of a second pinion gear 78. The rotor 87 engages the second pinon gear 78, so that rotation of the rotor 87 rotates the second pinion gear 78. A second roller bearing gear 80 is rotatably mounted to the left side of the front solar panel frame 58 and rotates freely. The second roller bearing gear 80 is located between fourth and fifth roller bearings 82, 84 located on the left side of the front solar panel frame 58. A sixth roller bearing 86 is located forwardly from the second roller bearing gear 80 and fourth roller bearing 82. The fourth, fifth, and sixth roller bearings are rotatably mounted on the exterior side of the front solar panel frame 58 with the rotating axes of the roller bearings being located higher than the axis of rotation of the second roller bearing gear, such that the highest points of the roller bearings 82, 84, 86 are higher than the highest point of the second roller bearing gear 80.

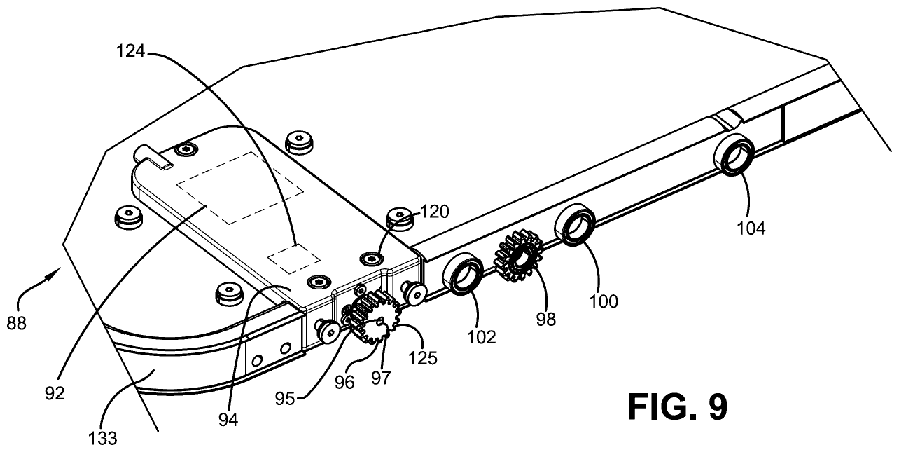

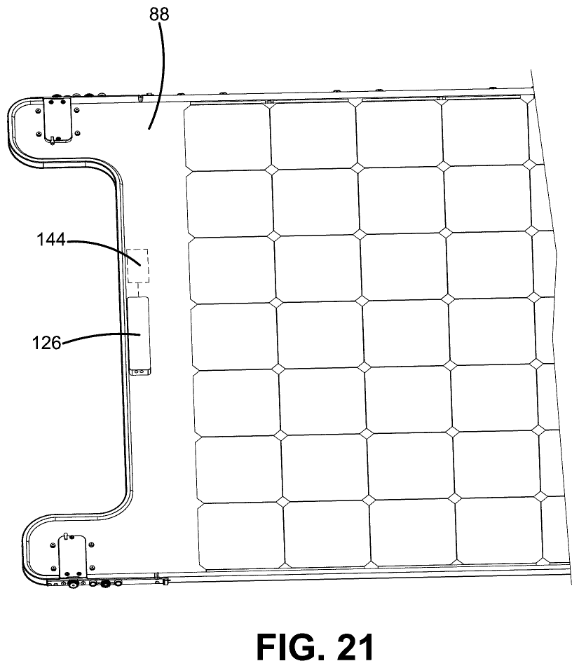

The solar panel assembly 20 also includes a rear solar panel 88 as seen in FIGS. 3 and 6. The rear solar panel 88 includes include a body 91 that has solar cells 93 on both the top and bottom surface of the rear solar panel 88. The rear solar panel 88 includes a rear solar panel frame 90 that surrounds the peripheral end of the body 91 and is attached to body 91. As illustrated in FIG. 9, a third motor 92 is mounted in a third motor compartment 94 of the rear solar panel frame 90 near the front right corner of the rear solar panel frame 90. The third motor 92 may be powered by a power source such as the vehicle battery or a small rechargeable battery 144 (FIG. 21) in the rear solar panel 88. The rechargeable battery 144 may be charged by the rear solar panel 88. The third motor 92 includes a rotor or shaft 95 that is D-shaped in cross section. The rotor 95 of the third motor 92 extends through the third motor compartment 94, the right side of the rear solar panel frame 90 and through a corresponding D-shaped bore 97 of a third pinion gear 96. The rotor engages the third pinon gear 96, so that rotation of the rotor rotates the third pinion gear 96. A third roller bearing gear 98 is rotatably mounted to the right side of the rear solar panel frame 90 and rotates freely. The third roller bearing gear 98 is located between seventh and eighth roller bearings 100, 102 located on the right side of the rear solar panel frame 90. A ninth roller bearing 104 is located rearwardly from the third roller bearing gear 98 and seventh roller bearing 100. The seventh, eighth, and ninth roller bearings 100, 102, 104 are rotatably mounted on the exterior side of the rear solar panel frame 90 with the rotating axes of the roller bearings 100, 102, 104 being located higher than the axis of rotation of the third roller bearing gear 98, such that the highest points of the roller bearings 100, 102, 104 are higher than the highest point of the third roller bearing gear 98.

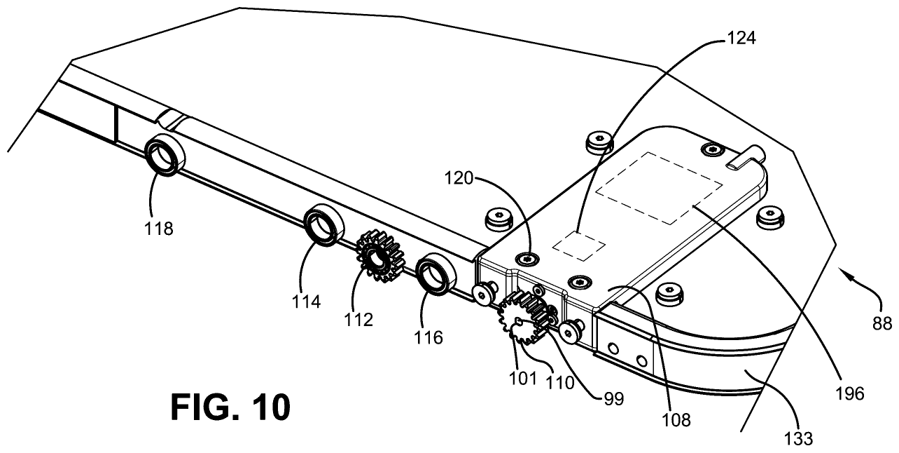

As illustrated in FIG. 10, a fourth motor 106 is mounted in a fourth motor compartment 108 of the rear solar panel frame 90 near the front left corner of the rear solar panel frame 90. The fourth motor 106 may be powered by a power source such as the vehicle battery or the rechargeable battery 144. The fourth motor 106 includes a rotor or shaft 99 that is D-shaped in cross section. The rotor 99 of the fourth motor 106 extends through the fourth motor compartment 108, the left side of the rear solar panel frame 90 and through a corresponding D-shaped bore 101 of a fourth pinion gear 110. The rotor 99 engages the fourth pinon gear 110, so that rotation of the rotor 99 rotates the fourth pinion gear 110. A fourth roller bearing gear 112 is rotatably mounted to the left side of the rear solar panel frame 90 and rotates freely. The fourth roller bearing gear 112 is located between tenth and eleventh roller bearings 114, 116 located on the left side of the rear solar panel frame 90. A twelfth roller bearing 118 is located rearwardly from the fourth roller bearing gear 112 and the tenth roller bearing 114. The tenth, eleventh, and twelfth roller bearings 114, 116, 118 are rotatably mounted on the exterior side of the rear solar panel frame 90 with the rotating axes of the roller bearings being located higher than the axis of rotation of the fourth roller bearing gear 112, such that the highest points of the roller bearings 100, 102, 104 are higher than the highest point of the fourth roller bearing gear 112. Each of the motor compartments may be covered by a cover fastened thereto by suitable fasteners such as hex-shaped recess head screws 120.

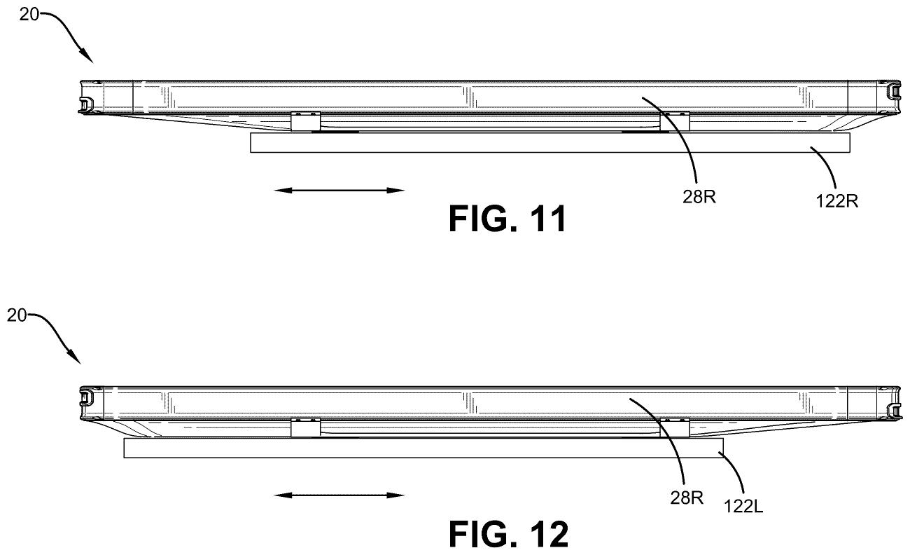

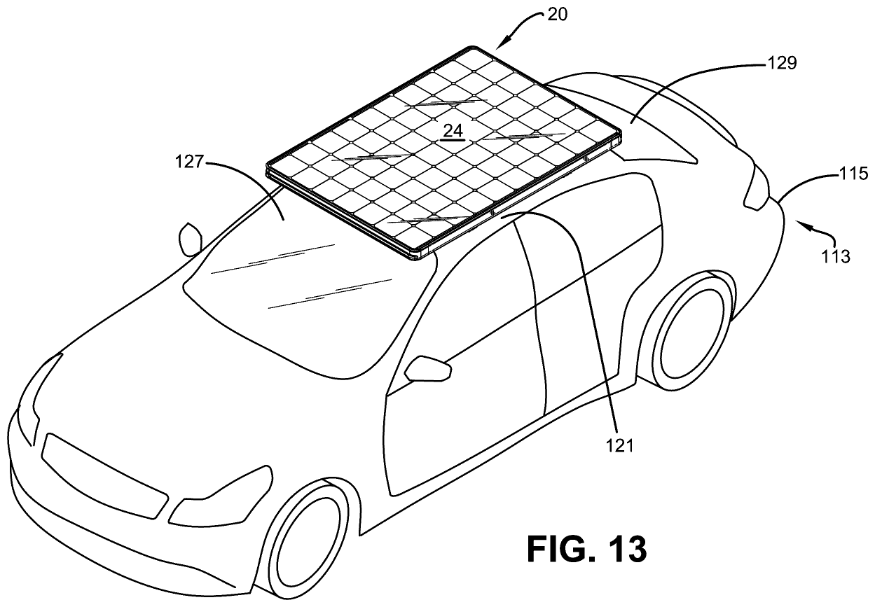

The front and rear side frame members 30, 32 are attached to the right and left side frame members 28R, 28L. The front side frame member 30 has a lower opening 109 (FIG. 1) and the rear side frame member 32 has an upper opening 111 (FIG. 2). The solar panel assembly 20 may be mounted on the vehicle roof in any way including but not limited to cross bars, vacuum suction cups, welding, and with bolts. In one example, the solar panel assembly may be mounted to right and left roof racks 122R, 122L mounted on a vehicle 113 (FIG. 6) as shown in FIGS. 11 and 12. The solar panel assembly 20 may be slidably mounted to the right and left roof racks 122R, 122L or otherwise slidably mounted on a roof 121 (FIG. 6) of the vehicle 113. This enables the solar panel assembly 20 to slide forwardly when mounted on the vehicle 113 so that the rear solar panel 90 does not rearwardly extend beyond a rear portion 115 (FIG. 6) of the vehicle 113, since the rear portion 115 of the vehicle 113 is shorter in length than a front portion 119 (FIG. 6) of the vehicle 113. The solar panel assembly 20 may be removeable mounted to the roof 121 in a manner that makes removal of the solar panel assembly 20 from the roof easy. This may be desirable if a user plans a long road trip with the electric vehicle and wants to easily remove the solar panel assembly 20 to improve vehicle aerodynamics and reduce the weight of the vehicle. FIG. 13 shows the solar panel assembly 20 mounted on the roof 121 of the electric vehicle 113 in the retracted position.

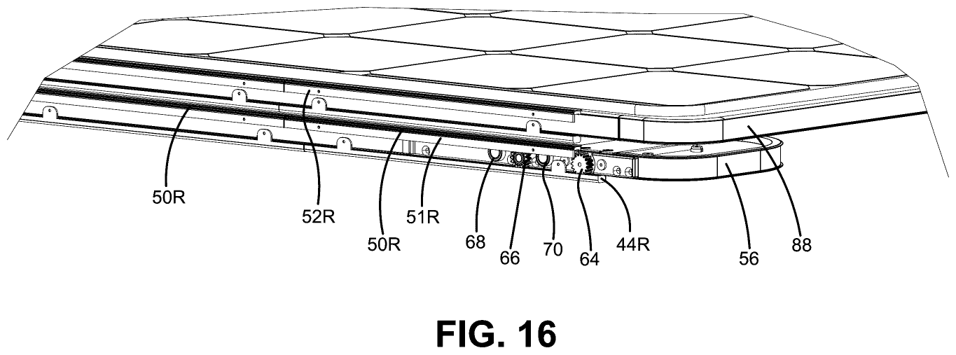

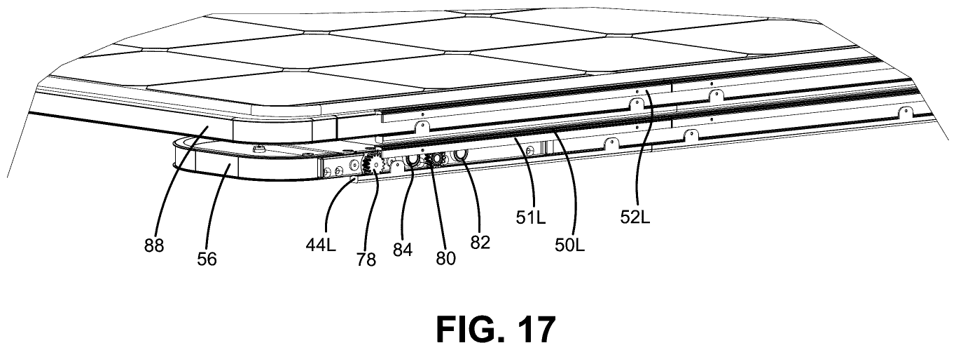

Referring to FIGS. 13-17, in the retracted position, the front solar panel 56 is inside the housing 22 with teeth 123 (FIG. 7) of the first pinion gear 64 and the first roller bearing gear 66 in meshing engagement with the teeth 251 (FIG. 4) of the right lower rack 44R, and teeth 125 (FIG. 8) of the second pinion gear 78 and the second roller bearing gear 80 in meshing engagement with the teeth 251 of the left lower rack 44L. In this retracted position also, the first, second, and third roller bearings 68, 70, 72 contact the right lower rail 51R and the fourth, fifth, and sixth roller bearings 82, 84, 86 contact the left lower rail 51L.

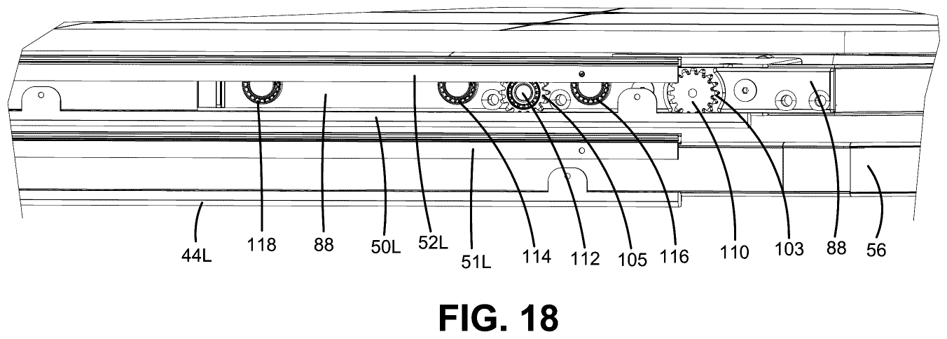

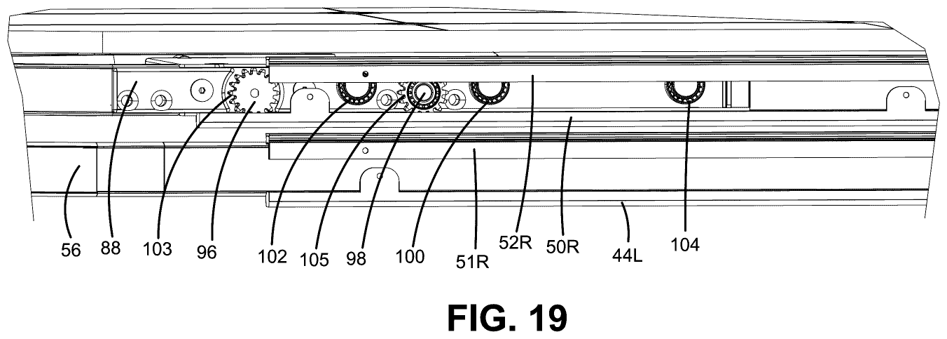

Also, with reference to FIGS. 13-15, 18 and 19, in the retracted position, the rear solar panel 88 is inside the housing 22 with teeth 103, 105 (FIG. 19) of the third pinion gear 96 and the third roller bearing gear 98 in meshing engagement with the teeth 61 of the right upper rack 50R as seen in FIG. 19, and teeth 107, 117 (FIG. 18) of the fourth pinion gear 110 and the fourth roller bearing gear 112 in meshing engagement with the teeth 61 of the left upper rack 50L as seen in FIG. 18. In this retracted position also, the seventh, eighth, and ninth roller bearings 100, 102, 104 contact the right upper rail 52R as seen in FIG. 19 and the tenth, eleventh, and twelfth roller bearings 114, 116, 118 contact the left upper rail 52L as seen in FIG. 18.

The solar panel assembly 20 may be moved to an extended position as shown in FIGS. 3 and 6. In particular, the motors are energized to cause the rotors to rotate, which in turn rotates their respective pinon gears. For the front solar panel 56, the first and second pinion gears 64, 78 are rotated counterclockwise (as viewed from the right side of the solar panel assembly 20), which causes the front solar panel 56 to move forwardly out of the lower opening 109 at a predetermined distance after the first and second motors 60, 74 are energized. The first and second motors 69, 74 may be energized by a user pushing a push button on the vehicle or alternatively, inputs from a remote-control device or other portable device such as a cell phone. The solar panel assembly 20 may be configured such that the user may keep pushing the push button until the front solar panel 56 extends out at a selected distance at which the user can then release the push button to stop the movement of the front solar panel 56. The first and second roller bearing gears 66, 80 rotate counterclockwise freely and engage the right and left lower racks 44R, 44L to support the front solar panel 56 as it moves and reciprocates along the lower racks. Also, during this movement of the front solar panel 56, the first through sixth roller bearings maintain contact with their respective right and left lower rails 51R, 51L (see FIGS. 25 and 26) to keep the first and second pinion gears 64, 78 and first and second roller bearing gears 66, 80 in meshing engagement with the right and left lower racks 44R, 44L to prevent the front solar panel 56 from disengaging from the right and left lower racks 44R, 44L.

For the rear solar panel 88, the third and fourth pinion gears 96, 110 are rotated clockwise (as viewed from the right side of the solar panel assembly 20), which causes the rear solar panel 88 to move rearwardly out of the upper opening 111 at a predetermined distance after the third and fourth motors 92, 106 are energized. The third and fourth roller bearing gears 98, 112 rotate clockwise freely and engage the right and left upper racks 50R, 50L to support the rear solar panel 88 as it moves and reciprocates along the upper racks. Also, during this movement of the rear solar panel 88, the seventh through twelfth roller bearings maintain contact with their respective right and left upper rails 52R, 52L (see FIGS. 27 and 28) to keep the third and fourth pinion gears 96, 110 and third and fourth roller bear gears 98, 112 in meshing engagement with the right and left upper racks 50R, 50L to prevent the rear solar panel 88 from disengaging from the right and left upper racks 50R, 50L.

The third and fourth motors 92, 106 may be energized by a user pushing a push button on the vehicle or alternatively, by operating inputs from a remote control device or other portable device such as a cell phone. A pair of limiter switches 124 (FIGS. 7-10) may be provided on the rear end 131 of the front solar panel 56 and front end 133 of the rear solar panel 88 to stop the pinion gears 64, 78, 96, 110 rotation when the rear solar panel 88 or the front solar panel 56 is fully out in the extended position or fully in in the retracted position. Proximity sensors 134 (FIG. 3) may be provided at the rear end 135 of the rear solar panel 88 or front end 137 of the front solar panel 56 to stop the respective front or rear solar panel from sliding further if it will hit an obstacle such as a tree branch or pole detected by the proximity sensors 134. The solar panel assembly 20 may be configured such that the user may keep pushing the push button until the rear solar panel 88 extends out at a selected distance at which the user can then release the push button to stop the movement of the rear solar panel 88.

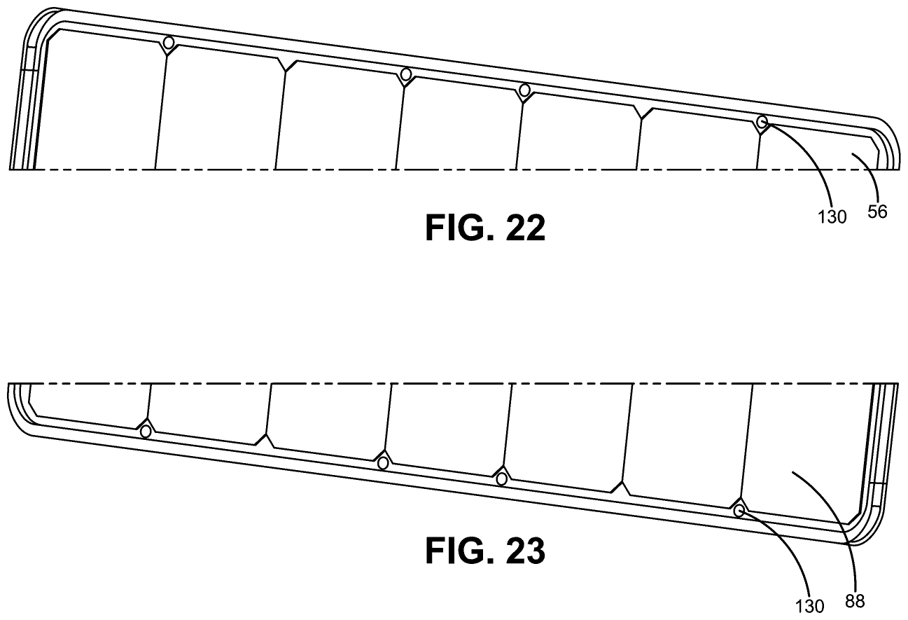

In the extended position more solar cells are exposed to sunlight. In addition to the solar cells 34 on top of the top solar panel 24 being exposed to sunlight, the solar cells 81, 93 on top of the front and rear solar panels 56, 88 are exposed to the sunlight. Thus, the solar cells can absorb more sunlight from the sun to generate more solar power to supply the electric vehicle. The front and rear solar panels 56, 88 also have solar cells 81, 93 on their bottoms that also absorb sunlight to provide additional power to supply the electric vehicle though not they are not directly exposed to the sun. The extended position is desirable for when the vehicle is parked and not being driven. The front and rear solar panels 56, 88 could use bifacial cells on the top and bottom sides that would be a lower cost implementation but produce less power. Strategically located drain holes 130 may be provided in the front and rear solar panels 56. 88 as shown in FIGS. 22 and 23.

The solar panel assembly 20 may be moved back to the retracted position, by pushing the same or a different button or by operating inputs from a remote-control device or other portable device such as a cell phone to energize the motors and cause the rotors to rotate in the opposite direction, which in turn rotates their respective pinon gears. For the front solar panel 56, the first and second pinion gears 64, 78 are rotated clockwise (as viewed from the right side of the solar panel assembly 20), which causes the front solar panel 56 to move rearwardly through the lower opening 109 and completely back into the housing 22. For the rear solar panel 88, the third and fourth pinion gears 96, 110 are rotated counterclockwise (as viewed from the right side of the solar panel assembly 20), which causes the rear solar panel 88 to move forwardly through the upper opening 111 and completely back into the housing 22. In the retracted position, the front and rear solar panels 56, 88 do not cover the front and rear windshield 127, 129 (FIG. 13) so as to not obscure the driver's and passenger's view through front and rear windshields 127, 129. This retracted position is desirable when the vehicle is being driven. Other suitable ways may be used to extend and retract the front and rear solar panels such as hydraulic, pneumatic, screw mount, or magnetic.

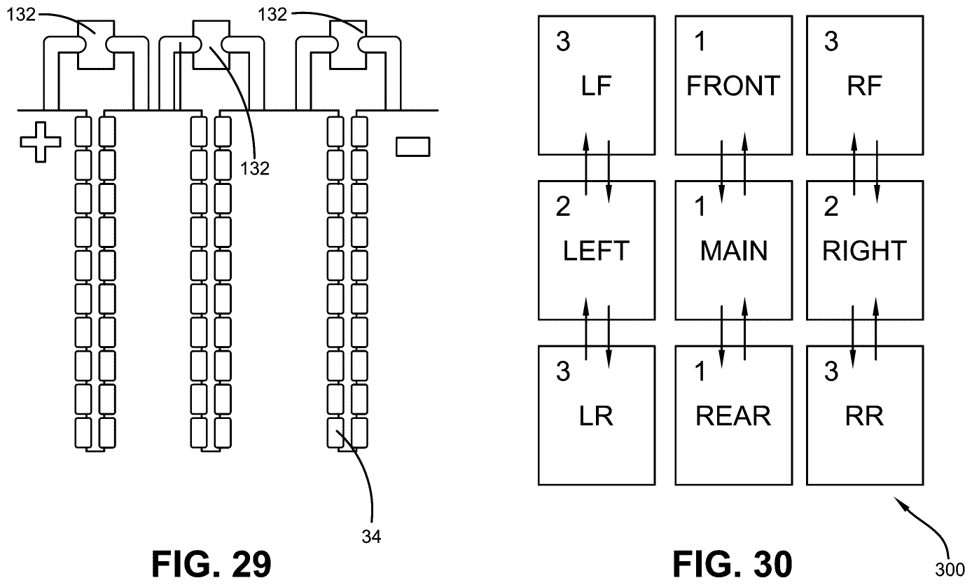

The solar panel assembly 20 may be configured so that the user has the option to extend the front solar panel 56 and keep the rear solar panel 88 retracted or extend the rear solar panel 88 and keep the rear solar panel 88 retracted. The solar panel assembly 20 could be wider and longer or smaller to adjust to different size cars as desired. The solar cells may be a variety of shapes such square or circular. The solar cells could be of any manufacturing technique or chemistry including but not limited to crystalline cells, amorphous cells, Silicone based cells, Gallium based cells, in form of a wafer, or thin film or in any other form. Also, cell level bypass diodes 132 may be provided as illustrated in FIG. 29. Cell level bypass diodes 132 operate as follows. If there is any single or random sets of solar cells 34 that receive a shadow, or are covered with an object such as snow, bird dropping or leaves, the cell level bypass diodes enable only those covered solar cells to be bypassed and the rest of the uncovered solar cells will continue to work and supply power. Alternatively, string level or even cell level MPPT (Maximum power point transfer) may also be used instead of cell level bypass diodes. This will allow the weaker panel, string or solar cell to generate power instead of being bypassed as the MPPT extracts maximum power point from the respective panel, string or solar cell.

In an alternative version, highly flexible thin film solar panels made of amorphous, crystalline or any solar technology maybe rolled or wound up and unwound instead of sliding in and out of the housing 22. As seen in FIGS. 20 and 21, a junction box 126 may be provided in each of the solar panels 56, 88 from which the wires come out to connect to an inverter 140 housed in the bottom cover or tray. There are physical cells on front and back of the slider. One could use bifacial solar cells (cells that produce power from both front and back), which reduces cost even though they a significant drop in generation from the back. Alternatively, solar cells may be located only on the top sides of the front and rear solar panels 56, 88. In another embodiment as shown in FIG. 30, the solar panel assembly 20 may have another set of six solar panels. In particular, three solar panels may slide out from the right side of the housing and three solar panels may slide out from the left side of the housing. Then, for each group of three solar panels when extended, one panel may slide forwardly and another panel may slide rearwardly. Various combinations of panels may slide out. For example, in a first phase, the front and rear solar panels slide out from top or main solar panel. In a second phase, the right group, left group, front and rear solar panels slide out from the main solar panel. In a third phase, the right group, left group, front and rear solar panels slide out from the main solar panel, the left front and left rear solar panels slide out from the left solar panel, and the right front and right rear solar panels slide out from the right solar panel. Alternatively, the two groups of three solar panels may slide out from the main solar panel at the front and rear instead of the right and left. So, in the third phase, the front group, rear group, right and left solar panels slide out from the main solar panel, the left front and right front solar panels slide out from the front solar panel, and the right rear and left rear solar panels slide out from the rear solar panel. All of the other components of the second embodiment are similar in structure and function as that of the first embodiment of the present invention.

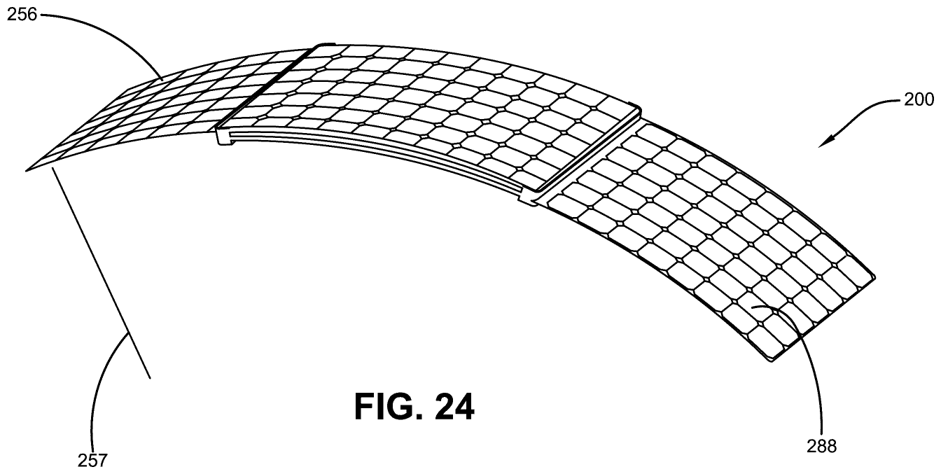

FIG. 24 shows a second embodiment of the present invention in the extended position in which the solar panel assembly 200 is convexly curved to correspond to the shape of the roof and front and rear windshields of the vehicle. In the extended position, the front solar panel 256 is also convexly curved to correspond to the shape of the front windshield, and rear solar panel 288 is convexly curved to correspond to the shape of the rear windshield. This makes the solar panel assembly more aesthetically appealing and enhanced aerodynamics. The right and left upper and lower racks, rails, and side frame members are similar in structure and function to that of the first embodiment except that they are convexly curved. All of the other components of the second embodiment are similar in structure and function as that of the first embodiment of the present invention. In all embodiments, there may be a front catch or gripping mechanism 257 that grips the front end of the front solar panel and a rear catch of gripping mechanism that grips the rear end of the real solar panel to stabilize them and prevent them flapping in the wind. In alternative versions, the solar panel may be part of the roof of the vehicle.

An AC 110V waterproof socket 136 (schematically shown in FIG. 3) is added to the solar panel assembly 20 to enable an existing electric vehicle charger to plug in it to charge the electric vehicle, or plug in two electric vehicle chargers and charge two cars at half the rate, or use the socket to charge electric vehicles and also use the power for homes in case of power outages or use the socket to power a camping battery. The solar panel assembly 20 may have a tracking system attached to it at the back allowing solar modules to track the sun. The solar panel assembly 20 may tilt partially or fully toward the sun. This would increase the generation by thirty percent for single axis tilt and forty percent for dual axis tilt. The solar panel assembly 20 may be configured to allow charging by hot wiring the solar panel assembly 20 to the electric vehicle at a service center. An adaptation kit may be included that will allow the solar panel assembly 20 to charge the electric vehicle from the top solar panel 24 without sliding out the front and rear solar panels 56, 88 even when the electric vehicle is driving or charging the car with the front and rear solar panels 56, 88 extended when the electric vehicle is parked at a parking lot without physically plugging in the electric vehicle. The rails may be made of nylon or other suitable low friction type material. In both embodiments, the solar panel assembly 20 may be turned horizontally 180 degrees and mounted on the vehicle such that the upper opening 111 is located at the front of the solar panel assembly 20 and the lower opening 109 is located at the rear of the solar panel assembly 20.

### Control Architecture and Sensor Fusion

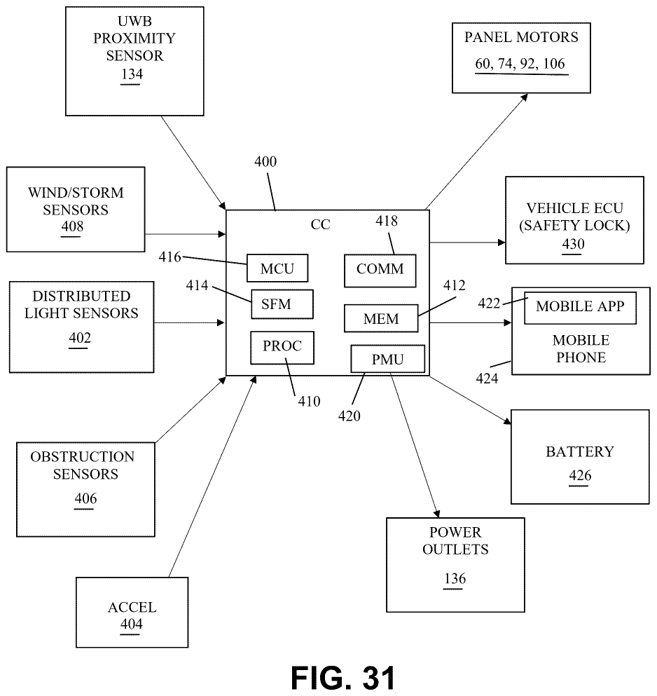

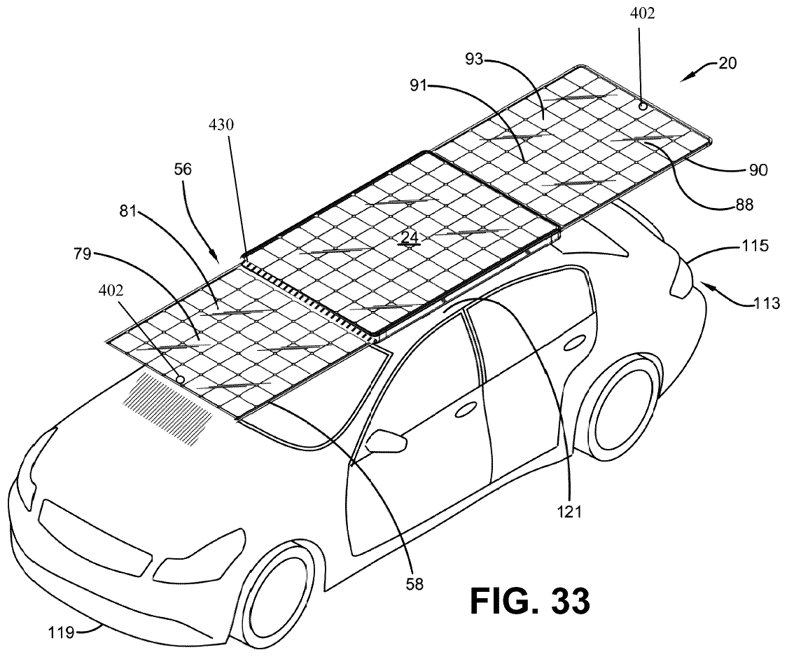

As illustrated in FIG. 31, the solar panel assembly 20 may include a central controller 400 configured to execute sensor fusion logic. The controller 400 combines inputs from light, motion, obstruction, and environmental sensors 402, 404, 406, 408 through a rule-based or adaptive decision engine to determine the precise timing and extent of panel deployment. The central controller 400 comprises a suite of integrated computing components configured to execute the adaptive deployment logic. Internally, the controller 400 includes a high-speed Processor (PROC) 410 and associated Memory (MEM) 412 for storing and executing sensor fusion algorithms. A Sensor Fusion Module (SFM) 414 is provided to synthesize concurrent data streams from the distributed light sensors 402, proximity sensors 134, and wind sensors 408 into a unified environmental model. The controller 400 further includes a Microcontroller Unit (MCU) 416 for managing real-time hardware interrupts and Communication Elements (COMM) 418, such as Bluetooth, Wi-Fi, or cellular transceivers, configured to facilitate wireless data exchange with a user mobile device and the vehicle's onboard diagnostics. Finally, a Power Management Unit (PMU) 420 is provided to regulate energy distribution between the solar panels, the vehicle battery, and the integrated power export outlets. This internal architecture allows the controller 400 to transition between various operational modes, such as the shade-avoidance partial deployment illustrated in FIG. 33, with millisecond latency.

### Automatic Deployment & Retraction Logic

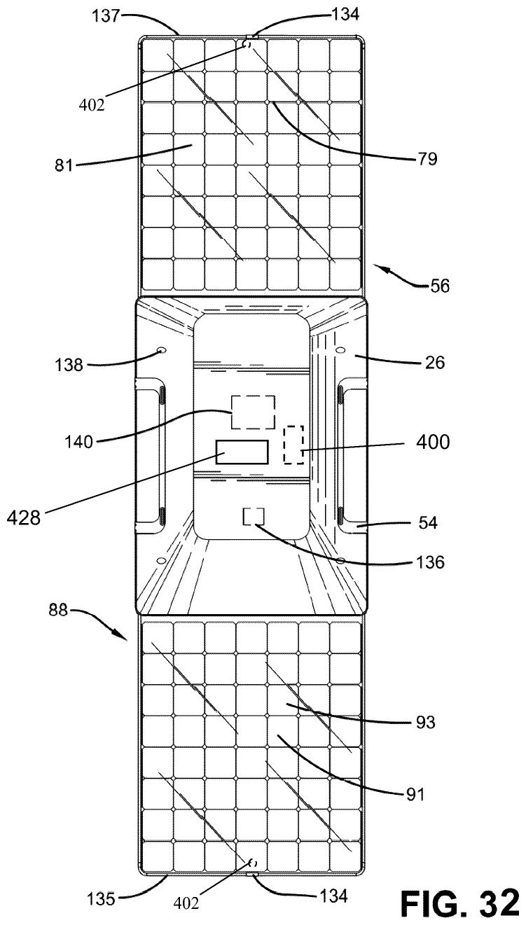

The system may comprise proximity-based automatic deployment using ultra-wideband (UWB) communication or other short-range wireless technologies. When an authorized user comes within a predefined radius of the vehicle, the system automatically deploys the front and rear solar panels 56, 88. Conversely, the panels 56, 88 automatically retract when the user exits the predefined radius, enabling a seamless, hands-free experience without manual input. As illustrated in the control architecture of FIG. 31 and the physical distribution of FIG. 32, this may be accomplished by including at least one of the proximity sensors 134. In a preferred embodiment, the proximity sensor 134 is an Ultra-Wideband (UWB) sensor, though infrared, ultrasonic, or LiDAR sensors may also be utilized. The proximity sensor 134 is configured to emit a detection field around the perimeter of the vehicle to identify physical obstructions—such as walls, other vehicles, or pedestrians—that may interfere with the path of the movable solar panels 56, 88. Data from the proximity sensor 134 is processed by the Sensor Fusion Module (SFM) 414 to ensure that panel extension is automatically halted or reversed if a physical collision is imminent, providing a safety override that operates in conjunction with the light-sensing logic

### Light-Based Sensing and Optimization

Distributed light sensors 402 are positioned across the system to detect uneven lighting conditions across different regions of the vehicle. The controller 400 utilizes ambient light sensing to inhibit deployment if available light falls below a threshold, making deployment inefficient. Furthermore, the system supports dynamic deployment percentage control, allowing the panels 56, 88 to stop at intermediate positions (e.g., 70% or 80%). This partial deployment prevents efficiency loss caused by partial shading of solar cells caused by for example, parking the vehicle in a way that half of the vehicle under the shade. The solar panel assembly 20 includes an intelligent deployment optimization system configured to maximize energy harvest while mitigating the negative effects of partial shading. The central controller 400 monitors real-time solar irradiance data via the distributed light sensors 402 during the movement of the front and rear solar panels 56, 88.

In one embodiment, the controller 400 is configured to stop the extension of a solar panel at an intermediate position based on detected environmental shading. For example, during an extension sequence, if the sensors 402 detect that the front solar panel 56 is approaching a shadowed region (e.g., from a nearby building or tree) at 70% of its full travel, the controller automatically halts the movement at that 70% threshold. By preventing the panel from extending into the shaded area, the system avoids the disproportionate efficiency losses typically associated with partial shading of a solar cell string. This adaptive logic allows the system to dynamically optimize the deployment percentage in real-time, ensuring that only the portions of the assembly capable of maximum performance are exposed to the environment.

### Environmental and Safety Sensors

The solar panel assembly 20 incorporates the environmental sensors 408 for wind and storm detection, utilizing pressure, vibration, or wind sensors to trigger automatic retraction during severe weather. The environmental sensors 408 may include at least one wind sensor configured to detect wind pressure acting upon the solar panel assembly 20. The controller 400 is programmed to compare the detected wind pressure against a pre-stored threshold wind speed value. Upon determining that the ambient wind speed exceeds this threshold, the controller 400 initiates an automatic retraction of the movable solar panels 56, 88 to protect the structural integrity of the assembly and the vehicle roof. The obstruction detection sensors 406 monitor the front, rear, left, and right of the vehicle to prevent deployment when obstacles are detected. Additionally, human presence detection allows the system to detect a person near the vehicle—such as when opening a trunk or doors—causing the panels to retract or halt to avoid interference or injury.

The controller 400 is configured to inhibit deployment if an obstacle is detected within the path of travel of the front or rear solar panels 56, 88. In one embodiment, the system includes human presence detection specifically configured to detect a person in proximity to the vehicle's functional areas, such as the front hood or the rear trunk (boot). For example, if the system detects a person approaching the rear of the vehicle to access the trunk while the rear solar panel 88 is extended, the controller 400 may automatically trigger a retraction command to move the panel out of the way, thereby preventing interference with the user or potential injury. This fail-safe logic ensures the panels “get out of the way” to allow for unobstructed human interaction with the vehicle's primary storage and access points.

### Vehicle Motion and Fail-Safe Logic

An accelerometer, reed switch, or other motion sensor 404 is used for vehicle motion detection. If the vehicle begins moving while panels are extended, the system triggers an automatic emergency retraction. The controller 400 also monitors for motor failure or jammed panels; if a stall is detected, a vehicle disablement safety interlock may be engaged to inhibit vehicle operation for safety.

### User Interface and Control

Users can control the system via a vehicle-integrated or mobile application 422 on a mobile phone 424 or other device allowing for remote deployment, retraction, or partial deployment. The app 422 enables the configuration of user-defined rules, such as “always deploy” or “deploy only when light is sufficient”. A manual override is provided to allow users to bypass automatic restrictions based on light, wind, or efficiency. In one embodiment, the solar panel assembly 20 is integrated with the vehicle's electronic control system such that it may be operated via an in-vehicle interface or a mobile application. This integration allows a user to deploy or retract the front and rear solar panels 56, 88 from within the vehicle cabin, in a manner analogous to the operation of a motorized sunroof.

The control interface provides the user with variable extension control, enabling the panels to be partially deployed to any intermediate position between the fully retracted and fully extended states. This is particularly advantageous during stationary charging sessions or while the user is inside the vehicle, allowing for customized solar exposure or clearance based on the immediate environment. The system may also be operated remotely through a cloud-based application, allowing the user to initiate deployment or retraction while away from the vehicle. Through the control interface of the mobile application 422, the user may manually define and adjust specific threshold light levels (e.g., in lumens or percentage of maximum irradiance) at which the controller 400 is triggered to automatically halt or inhibit panel deployment.

### Power Management and Export

The solar panel assembly 20 may utilize high-efficiency solar cells, such as triple-junction gallium arsenide cells, providing a significantly increased power density compared to conventional silicon-based panels. In certain embodiments, the solar panel assembly is configured to generate a power output in the range of 5 kW to 6 kW.

To utilize this high power output, the system includes an integrated power distribution module comprising external power outlets (illustrated as waterproof socket 136 in FIG. 32) for powering auxiliary equipment, such as camping gear or external tools. The controller 400 executes power path management and smart power-sharing logic to dynamically allocate energy between the vehicle's traction battery 426 and the external loads. For example, if the vehicle battery 426 reaches a threshold state of charge, the system smartly prioritizes and diverts power to the integrated outlets 136. This logic allows for simultaneous charging of the vehicle and operation of external equipment, optimizing the utility of the high-power solar generation in various stationary or off-grid environments.

### Vehicle Integration

The solar panel assembly 20 is configured for direct electrical integration with the vehicle's primary electrical architecture. Unlike systems requiring manual external plug-in connections, the present assembly is hardwired to the vehicle's power bus and control network. This permanent integration allows the system to operate automatically and seamlessly as a built-in vehicle feature, analogous to a factory-installed sunroof or automated spoiler, ensuring that power transfer and control signals are maintained without user intervention.

### Vehicle Motion and Fail-Safe Logic

To ensure operational safety, the system incorporates a vehicle disablement safety interlock 430. The central controller is configured to monitor the operational status of the motors 60, 74, 92, 106 and the position of the front and rear solar panels 56, 88. In the event that a motor failure or a mechanical jam is detected, the controller may transmit a signal to the vehicle's engine control unit (ECU) to inhibit vehicle operation, preventing the vehicle from being driven while the panels are in a potentially hazardous, non-retracted state.

Additionally, the assembly may include an internal motion sensing suite, such as an accelerometer, reed switch, or dedicated motion sensor. This suite acts as a redundant safety layer; if the vehicle begins to move while the panels are extended—whether due to sensor failure or user oversight—the motion sensing suite detects the displacement and triggers an automatic emergency retraction command. This ensures the panels are secured immediately upon vehicle movement to prevent structural damage or safety hazards.

### Mounting and Structural Variations

A quick-release mounting system allows for the removal of the entire assembly without tools. The housing 22 of the solar panel assembly may be provided in a plurality of structural configurations to suit specific vehicle requirements. In one embodiment, the housing 22 is configured with a slim profile design, wherein the vertical height of the side frame members 28, 30, 32 is minimized to bring the top solar panel 24 into close proximity with the vehicle roof, thereby reducing aerodynamic drag. In an alternative embodiment, the housing 22 is configured with an expanded depth to provide additional internal volume between the top solar panel 24 and the bottom cover panel 26. An under-housing or “belly” structure is utilized to accommodate electronics, inverters, and utility features.

### Storage and Utility Features

The solar panel assembly 20 may further include an integrated waterproof storage compartment 428 disposed within the lower portion or “belly” of the housing 22. This compartment 428 is configured to utilize the internal volume not occupied by the solar panels 56, 88 or associated electronics. As the miniaturization of electronic components and inverters progresses, the resulting unoccupied space within the housing 22 may be utilized for the storage of equipment, such as backpacks, tools, or outdoor gear. Referring to the underside of the assembly as shown in FIG. 32, the housing 22 includes the integrated waterproof socket 136 and the waterproof storage compartment. The waterproof socket 136 is electrically coupled to the Power Management Unit (PMU) 420 of the central controller 400, which is disposed within the housing and illustrated in dashed lines to indicate its internal position. By routing power through the central controller 400, the system can intelligently regulate the output to the socket 136 based on real-time solar harvest or vehicle battery levels. Adjacent to the socket 136, the waterproof storage compartment 428 provides a recessed, weather-protected volume for stowing peripheral cables or adapters used with the socket 136. This co-location of the controller 400, storage compartment 428, and socket 136 on the bottom surface of the housing ensures that all high-voltage interfaces remain shielded from environmental exposure while the panels 56, 88 are in either a stowed or extended position.

This integrated storage compartment may include a shock-absorbing internal lining, such as anti-shock foam, to protect stored items from vehicle vibration. The storage area is preferably aligned for ergonomic access when a user exits the vehicle. By integrating the storage directly into the solar panel housing, the system eliminates the need for a separate third-party roof box, providing a multi-functional utility system that serves as both a high-power energy generator and a waterproof cargo carrier. The assembly thus allows for a configurable tradeoff between a slim aerodynamic profile and increased storage volume based on user preference.

To maintain the movement mechanism, a rail-cleaning gasket system is provided. Gaskets located at the entry and exit points clean the rails 51, 52 and solar panels during movement, ensuring debris exclusion during extension and retraction and preventing dirt ingress into the internal rail. As illustrated in the partial deployment state of FIG. 33, the movable solar panels 56, 88 translate through the rail-cleaning gasket system 430, which maintains continuous contact with the panel surfaces to wipe away debris and prevent contaminants from entering the housing internal volume. system.

While the foregoing written description of the invention enables one of ordinary skill to make and use what is presently considered to be the best mode thereof, those of ordinary skill in the art will understand and appreciate the existence of variations, combinations, and equivalents of the specific embodiment, method, and examples herein. The invention should, therefore, not be limited by the above-described embodiments, method, and examples, but by all embodiments and methods within the scope and spirit of the invention.

What is claimed is:

1. A solar panel assembly for a vehicle comprising:
a housing comprising a top solar panel, a bottom cover panel, and a frame;
at least one movable solar panel configured to move between a retracted position within the housing and an extended position outside the housing;
a central controller disposed within the housing comprising a processor and a sensor fusion module; and
a light sensor in communication with the central controller, wherein the central controller is configured to detect a transition from a sunlit region to a shadowed region via the light sensor and automatically halt extension of the movable solar panel at an intermediate position based on the transition.

2. The solar panel assembly of claim 1, wherein the intermediate position is between 70% and 90% of a full travel distance of the movable solar panel.

3. The solar panel assembly of claim 1, wherein the light sensor is one of a plurality of distributed light sensors positioned across the housing to monitor ambient irradiance in real-time.

4. The solar panel assembly of claim 1, further comprising a user interface provided via a mobile application, wherein the mobile application allows a user to define a threshold light level for the automatic halting of the panel.

5. The solar panel assembly of claim 1, further comprising a rail-cleaning gasket system located at entry and exit points of the housing configured to exclude debris from the housing during movement of the movable solar panel.

6. A solar panel assembly for a vehicle, comprising:
a housing comprising at least one movable solar panel;
a central controller comprising a power management unit;
an integrated power distribution module comprising at least one external power outlet and an integrated waterproof storage compartment; and
a motion sensor configured to detect vehicle movement, wherein the central controller is configured to initiate an emergency retraction of the movable solar panel upon detection of vehicle movement via the motion sensor.

7. The solar panel assembly of claim 6, wherein the motion sensor comprises an accelerometer integrated within the central controller.

8. The solar panel assembly of claim 6, further comprising a vehicle disablement safety interlock, wherein the central controller inhibits vehicle operation upon detecting a mechanical jam of the movable solar panel.

9. The solar panel assembly of claim 6, wherein the power management unit executes a smart power-sharing logic to prioritize power delivery to the external power outlet when a vehicle traction battery reaches a threshold state of charge.

10. The solar panel assembly of claim 6, wherein the integrated waterproof storage compartment is disposed adjacent to the external power outlet and contains a shock-absorbing internal lining.

11. The solar panel assembly of claim 9, further comprising an environmental sensor configured to detect wind pressure, wherein the controller initiates retraction upon detecting a threshold wind speed.

12. A solar panel assembly for a vehicle, comprising:
a housing containing at least one movable solar panel;
a central controller comprising a sensor fusion module and a communication transceiver; and
a proximity sensor in communication with the central controller, wherein the central controller is configured to identify a presence of an authorized user within a predefined radius of the vehicle via the proximity sensor and automatically move the movable solar panel between a retracted and extended position based on the presence of the authorized user.

13. The solar panel assembly of claim 12, wherein the proximity sensor comprises an ultra-wideband (UWB) sensor.

14. The solar panel assembly of claim 12, wherein the proximity sensor is configured to detect human presence near a functional area of the vehicle, and wherein the central controller halts movement of the panel to avoid interference with the user.

15. The solar panel assembly of claim 14, wherein the functional area comprises a vehicle trunk or a vehicle hood.

16. The solar panel assembly of claim 12, wherein the communication transceiver facilitates data exchange with a mobile device to allow manual override of the proximity sensor.

17. The solar panel assembly of claim 12, wherein the housing further comprises a quick-release mounting system configured for removal of the assembly from the vehicle without tools.

18. The solar panel assembly of claim 12, wherein the movable solar panel comprises triple-junction gallium arsenide solar cells.

19. The solar panel assembly of claim 18, wherein the assembly is configured to generate a power output in the range of 5 kW to 6 kW.

20. The solar panel assembly of claim 12, wherein the assembly is hardwired to a vehicle power bus and control network for seamless electrical integration.
